(19) United States
(12) Patent Application Publication
(10) Pub. No.: US 2012/0038425 A1
(43) Pub. Date: Feb. 16, 2012

(54) Voltage controlled oscillator

(75) Inventor: Junichiro Yamakawa, Sayama-shi (JP)

(73) Assignee: Nihon Dempa Kohyo Co., Ltd., Shibuya-ku (JP)

(21) Appl. No.: 13/136,591

(22) Filed: Aug. 4, 2011

(30) Foreign Application Priority Data
Aug. 11, 2010 (JP) 2010-180524

(51) Int. Cl. H03L 7/00

(52) U.S. Cl. 331/8

(57) ABSTRACT

A resonance part of a voltage controlled oscillator (VCO) includes variable capacitance elements where an electrostatic capacitance changes in order to adjust a resonance frequency and an inductance element, and a transistor of grounded emitter type amplifies a frequency signal inputted from the resonance part to a base terminal. A feedback part includes capacitance elements for feedback, and feedbacks a frequency signal outputted from an emitter terminal of the transistor to the transistor via the base terminal. Besides, base bleeder resistances for adjusting a bias voltage to be applied to the base terminal and the transistor are formed in a common integrated circuit, and an emitter resistance is provided outside the integrated circuit as a resistance element being a different body in order to adjust an operating point of the transistor.

### BACKGROUND OF THE INVENTION

1. Field of the Invention

The present invention relates to a voltage controlled oscillator (VCO) which includes a resonance part configured by using an inductance element and a variable capacitance element.

2. Description of the Related Art

The present applicant is developing a small-sized voltage controlled oscillator (hereinafter, referred to as a VCO) which is capable of outputting a frequency signal of a high frequency band such as of several GHz to several tens GHz. FIG. 11 is a circuit diagram showing a configuration example of a VCO before improvement according to the present invention is done. The VCO has a configuration in which a Colpitts oscillation circuit composed of a transistor 21 of grounded emitter type and a feedback part 2 which feedbacks a frequency signal to the transistor 21 is connected to a resonance part 1 that includes first and second varicap diodes 13, 14 being variable capacitance elements and an inductance element 11, and an oscillation loop is formed by those transistor 21, feed-back part 2, and resonance part 1.

With regard to the VCO, downsizing of a device and reduction of a manufacturing cost are promoted by forming the transistor 21 whose design change is comparatively small, buffer amplifiers 31, 32 in a subsequent stage thereof, and a frequency dividing circuit 33 inside a common IC circuit part 3 (integrated circuit).

Further, in general, a bias circuit for adjusting a bias voltage supplied to a base terminal is connected to the transistor 21. In an example shown in FIG. 11, a current feedback type bias circuit is formed by base bleeder resistances R2, R3 connected to a bias terminal of the transistor 21 and an emitter resistance R1 connected to an emitter terminal.

The bias circuit is capable of adjusting an operating point of the transistor 21 by changing a resistance value of the base bleeder resistances R2, R3 or the emitter resistance R1, and a suitable resistance value is chosen accordingly in correspondence with a range of an oscillation frequency of the VCO, for example. Thus, as a concrete configuration of each of resistances R1 to R3 in the bias circuit, it seems more advantageous to choose a resistance element being a different body from the IC circuit part 3 accordingly and to connect the resistance element to the transistor 21 inside the IC circuit part 3 than to form those resistances R1 to R3 inside the IC circuit part 3, since a trouble, a cost and so on for preparing masks for creation of IC circuit parts 3 different by an oscillation frequency can be omitted.

Thus, if the IC circuit part 3 which includes the transistor 21 and the resistance elements R1 to R3 constituting its bias circuit are different bodies, those IC circuit part 3 and resistance elements R1 to R3 are connected to each other via wirings formed on a base substrate. For example, if surface mounting on a substrate is performed by general reflow soldering, those IC circuit 3 and resistance elements R1 to R3 are placed on a pad on a wiring coated with solder paste, and soldering is performed in a reflow furnace.

However, the present inventor has found a fact that if a VCO is configured by making a transistor 21 in an IC circuit part 3 and resistance elements R1 to R3 be different bodies as above, a level of a phase noise becomes large in a high frequency region of equal to or more than 5 GHz, of equal to or more than 10 GHz for example, deteriorating a frequency characteristic. Then, a cause of occurrence of such deterioration of the frequency characteristic is sought, and it is found that as schematically shown in FIG. 11 a stray capacitance is formed between a pad of the base bleeder resistances R2, R3 and a pad of the IC circuit part 3, bringing about deterioration of the frequency characteristic.

As a measure for reducing such a stray capacitance, it can be considered to enlarge a distance between the IC circuit 3 and the base bleeder resistances R2, R3. However, disposing those base bleeder resistances R2, R3 and IC circuit 3 apart from each other in a degree that the stray capacitance is not formed is contrary to a request of downsizing of a VCO and leads to increase of an inductance component and a resistance loss due to elongation of wirings.

Here, Patent Document 1 describes a VCO in which a transistor for buffer amplification of a frequency signal is cascade-connected in a subsequent stage of a transistor constituting a Colpitts oscillation circuit and the transistor for buffer amplification and resistances constituting its bias circuit are formed inside a common IC circuit. However, if all the bias circuits are housed in the IC circuit, a necessity occurs to create different IC circuits in correspondence with an oscillation frequency as stated above, causing cost increase in preparing various VCO's with different oscillation frequency ranges.
[Patent Document 1] Japanese Patent Application Laid-open No. Hei 8-167844: Paragraph 0019, FIG. 2

### SUMMARY OF THE INVENTION

The present invention is made under such circumstances and its object is to provide a voltage controlled oscillator which is small and has a good frequency characteristic.

A voltage controlled oscillator according to the present invention has:

a resonance part which includes a variable capacitance element where an electrostatic capacitance changes in correspondence with a control voltage for frequency control inputted from the outside, and an inductance element, and in which a resonance frequency is adjusted in correspondence with the electrostatic capacitance;

a transistor of grounded emitter type to amplify a frequency signal inputted from the resonance part to a base terminal;

a feedback part which includes a capacitance element for feedback, feedbacks a frequency signal outputted from an emitter terminal of the transistor to the transistor via the base terminal, and constitutes an oscillation loop together with the transistor and the resonance part;

a base bleeder resistance to adjust a bias voltage applied to the base terminal of the transistor; and

an emitter resistance which is provided between the emitter terminal of the transistor and a ground in order to adjust an operating point of the transistor,

wherein while the transistor and the base bleeder resistance are formed in a common integrated circuit, the emitter resistance is constituted by a resistance element being a different body from the integrated circuit, and the voltage controlled oscillator is configured by providing the integrated circuit, the resistance element, the resonance part, and the feedback part on a common substrate.

The voltage controlled oscillator can have the following features.

(a) The substrate is a quartz crystal substrate.

(b) The resonance frequency is equal to or more than 5 GHz.

According to the present invention, since base bleeder resistances are formed inside an integrated circuit common to a transistor, it is possible to reduce a stray capacitance which occurs between pads in an oscillation frequency region of high frequency when the base bleeder resistances and the integrated circuit are formed as different bodies. Further, with regard to an emitter resistance which gives small influence on occurrence of the stray capacitance, making the emitter resistance be a different body from the integrated circuit facilitates adjustment of an operating point of the transistor, compared with a case that the emitter resistance is also formed inside the integrated circuit.

### BRIEF DESCRIPTION OF THE DRAWINGS

FIG. 1 is a circuit diagram showing a configuration example of a voltage controlled oscillator (VCO) of the present embodiment;

FIG. 2 is a circuit diagram showing a modification example of the VCO;

FIG. 3 is a perspective view showing an external appearance configuration of the VCO;

FIG. 4 is a plan view of the VCO;

FIG. 5 is a side vide of the VCO;

FIG. 6 is an enlarged plan view showing a configuration of a connection part between an IC circuit part and a circuit part on substrate in the VCO;

FIG. 7 is a plan view showing a configuration of the circuit part on substrate provided on the VCO;

FIG. 8 is a side view of the circuit part on substrate;

FIG. 9 is an enlarged plan view of the circuit part on substrate;

FIG. 10 is a characteristic chart showing negative resistances to oscillation frequencies of the VCO's according to an example and comparative examples; and

FIG. 11 is a circuit view showing an example of a VCO before improvement.

### DETAILED DESCRIPTION OF THE PREFERRED EMBODIMENT(S)

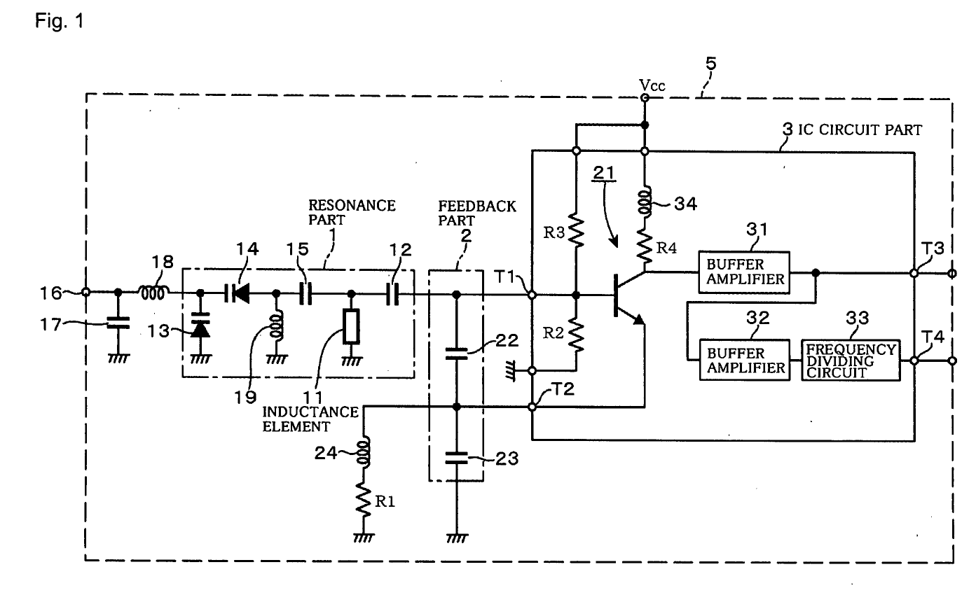

A configuration of a VCO according to an embodiment of the present invention will be described with reference to a circuit diagram of FIG. 1. In FIG. 1, a reference number 1 indicates a resonance part, and the resonance part 1 has a series circuit for series resonance of an inductance element 11 and a capacitor 12 being a capacitance element. To the inductance element 11, a first varicap diode 13 being a variable capacitance element and a series circuit constituted by a second varicap diode 14 and a capacitor 15 being a capacitance element are connected in parallel, thereby constituting a parallel circuit for parallel resonance. In other words, the resonance part 1 has a series resonance frequency (resonance point) of the series circuit and a parallel resonance frequency (antiresonance point) of the parallel circuit, and the frequency of the resonance point determines an oscillation frequency. In this example, a constant of each circuit element is set so that the resonance point becomes larger than the antiresonance point, and providing such an antiresonacne point steepens the frequency characteristic near the resonance point.

Further, in FIG. 1, a reference number 16 indicates an input terminal for control voltage, and by a control voltage supplied to the input terminal 16, capacitance values of the first varicap diode 13 and the second varicap diode 14 are adjusted, whereby the antiresonance point of the parallel circuit moves and consequently the resonance point also moves, so that the oscillation frequency is adjusted. A reason why the second varicap diode 14 is used in addition to the first varicap diode 13 is to increase a span of adjustment range of the frequency. A reference number 17 indicates a capacitor for voltage stabilization, and reference numbers 18 and 19 indicate inductors for bias.

Further, in a subsequent stage side of the resonance part 1, there are provided an NPN-type transistor 21 whose base is connected to a capacitor 12 inside the resonance part 1 and which is formed in the IC circuit part 3 being an integrated circuit, and a feedback part 2 for feedbacking an emitter output of the transistor 21 to the base. The feedback part 2 is configured by connecting two capacitors 22, 23 being capacitance elements for feedback in series, and the capacitor 22 in one side is connected between a base terminal and an emitter terminal of the transistor 21 while the capacitor 23 in the other side is connected between the emitter terminal of the transistor 21 and a ground, adjusting a voltage feedbacked to a base terminal side.

An emitter of the transistor 21 is connected to a connection point of the two capacitors 22, 23 of the feedback part 2, and is further grounded via an inductance 24 and an emitter resistance R1. Here, since the transistor 21 of this example is provided inside the IC circuit part 3 as stated above, the capacitors 12, 22 of the resonance part 1 and the feedback part 2 are connected to the base of the transistor 21 via a terminal T1 of a chip constituting the IC circuit part 3, and the respective capacitors 22, 23 of the is feedback part 2 and the inductor 24 are connected to the emitter of the transistor 21 via a terminal T2 of the chip. In this view point, the terminal T1 is equivalent to a base terminal of the present embodiment, and the terminal T2 is equivalent to an emitter terminal.

In the circuit of the VCO described above, an oscillation loop by the resonance part 1, the transistor 21, and the feedback part 2 is configured, and when the control voltage is inputted from the outside to the input terminal 16, the oscillation loop oscillates at an oscillation frequency corresponding to the resonance point of the resonance part 1. Inside the IC circuit part 3 are provided two buffer amplifiers 31, 32 connected to a collector of the transistor 21 for example, and from one buffer amplifier 31 an oscillation output (signal of an oscillation frequency) is retrieved via a terminal part T3, and from the other buffer amplifier 32 a frequency signal made by dividing the oscillation output in a frequency dividing circuit 33 is retrieved via a terminal part T4.

The VCO according to this example is capable of oscillating a frequency signal of a range of 6 GHz to 20 GHz, for example, by the oscillation loop, and it is designed so that a frequency signal with a best frequency characteristic at 10 GHz can be outputted. Hereinafter, a frequency adjusted so that a best characteristic can be obtained is referred to as a designed frequency.

It should be noted that the resonance part 1 can have a circuit configuration in which a varicap diode and an inductance element 11 are connected in series and an oscillation frequency is determined by a series oscillation frequency of this series circuit, and in such a case, the varicap diode doubles as a capacitance element of the resonance part 1 in claims of the present invention.

In the VCO described above, to the transistor 21 formed inside the IC circuit part 3, a bias circuit for adjusting a base voltage applied to the base is connected. Then, it is configured so that deterioration of the frequency characteristic due to a stray capacitance explained in Description of the Related Art can be suppressed. Hereinafter, a concrete configuration of the bias circuit will be described.

As shown in FIG. 1, the base bleeder resistances R2, R3 are a voltage dividing circuit for dividing a voltage Vcc applied by a DC power source and applying to the base of the transistor 21, and the resistance R3 is provided between the DC power source Vcc and the base and the resistance R2 is provided between the base and the ground. As described in Description of the Related Art, if the base bleeder resistances R2, R3 are constituted by resistance elements being different bodies from the IC circuit part 3, a stray capacitance occurs between pads linking the IC circuit 3 and the resistances R2, R3, causing deterioration of a frequency characteristic. Thus, in the VCO of the present embodiment, those base bleeder resistances R2, R3 are provided inside the IC circuit part 3 and a pad causing occurrence of a stray capacitance is eliminated, whereby improvement of a frequency characteristic is sought.

On the other hand, the emitter resistance R1 which adjusts a potential difference between the emitter of the transistor 21 and the ground is configured as a resistance element being a different body from the IC circuit part 3, and is disposed outside the IC circuit part 3. When the IC circuit 3 and the emitter resistance R1 are different bodies, those components are connected via a pad and it seems to cause occurrence of a stray capacitance. However, as shown in FIG. 1, the emitter resistance R1 is connected to the capacitor 23 constituting the feedback part 2, and if a capacitance value after deduction of the stray capacitance having occurred in the pad of the resistance R1 is to be a capacitance of the capacitor 23, influence can be eliminated equivalently.

Here, if the emitter resistance R1 is also formed inside the IC circuit part 3 in addition to the base bleeder resistances R2, R3 for example, for a purpose of reduction of the stray capacitance, it is not realistic to prepare a variety of IC circuit parts 3 in view of a trouble and a cost of creation of a mask in manufacturing the IC circuit 3 part. Thus, all that can be done is to prepare a few types of IC circuit parts 3 in which operation points of the transistors 21 are adjusted in advance, in correspondence with oscillation frequencies of the IC circuit parts 3 and so on, which is a constraint on preparing a variety of VCO's whose oscillation frequency ranges are different.

In this regard, as for the emitter resistance R1, between which and the IC circuit part 3 the stray capacitance is hard to occur, by configuring the emitter resistance R1 with the resistance element being the different body from the IC circuit part 3, changing of the resistance value of the emitter resistance R1 becomes easy and thus a degree of freedom in adjusting the operation point of the transistor 21 is increased.

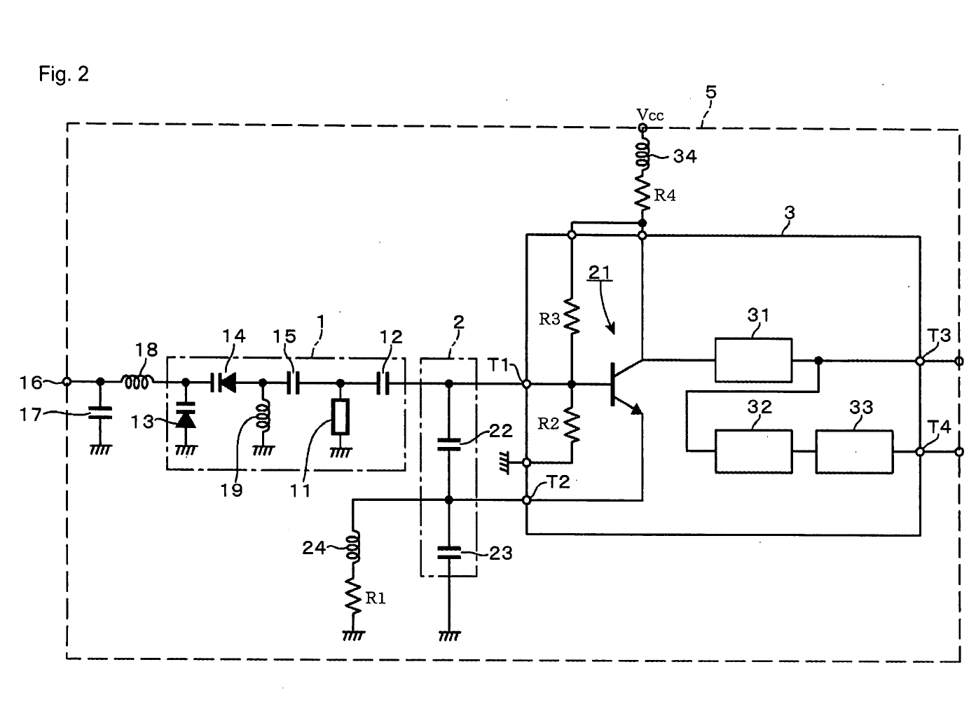

In FIG. 1, a reference signal R4 indicates a collector resistance for adjusting a DC voltage Vcc applied to a collector. It should be noted that what is applied to the R4 is the DC voltage, and thus even if the R4 is provided outside the IC circuit part 3 as shown in FIG. 2 for example, the oscillation characteristic is not largely influenced though a stray capacitance occurs.

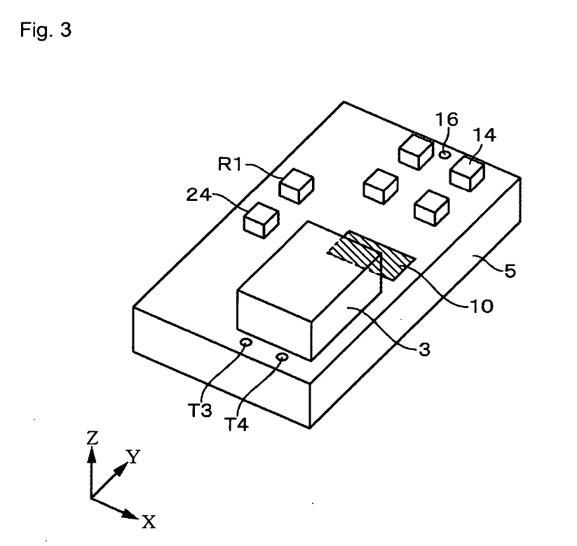

Next, a concrete overview of this VCO and a layout of the resonance part 1 and the feedback part 2 as well as the IC circuit part 3 will be described with reference to FIG. 3 to FIG. 9. The VCO according to this example is formed on an AT-cut quartz crystal substrate 5, and on the quartz crystal substrate 5 there are disposed electronic components such as a resonance part 1 and a feedback part 2 as well as an IC circuit part 3 and a peripheral part.

Here, a reason why the VCO is formed on the quartz crystal substrate 5 is described below. With regard to a VCO oscillating a frequency signal of a high frequency band as high as several GHz or several ten GHz, there is a possibility of becoming a distributed constant circuit in which a size of a substrate is longer than a wavelength of a frequency signal to be outputted. In such a case, it is anticipated that signals whose amplitudes are reversed flow on the substrate and those signals interfere each other and an electric signal is not outputted, or that the size of the substrate including the VCO is required to be downsized to a size hard to be fabricated in reality.

For example, if LTCC (Low Temperature Co-fired Ceramics) made of alumina (Al₂O₃), for example, is used as a base substrate, an apparent wavelength of an electric signal propagated on the substrate becomes shorter than an actual wavelength since a relative dielectric constant ∈ᵣ of the LTCC is about 9 to 10, for example. Therefore, in order to suppress interference of the electric signals, it is preferable that the size of the substrate is downsized to about one tenth, for example, of a wavelength of an electric signal, but in reality, it is difficult to form an electric circuit or mount an electronic component on a substrate of such a size

In this regard, the quartz crystal substrate 5 has a relative dielectric constant ∈ᵣ within a range of 3 to 5, of 3.8 for example, and a loss (dielectric loss tangent: tan δ) of an electric energy is about 0.00008, for example. Further, a Q value of the quartz crystal substrate 5 is about 12500 (=1/0.00008).

Here, a wavelength of the frequency signal of 10 GHz in vacuum is about 3 cm, but an apparent wavelength of that frequency signal becomes about 1.5 cm when the relative dielectric constant ∈ᵣ of the quartz crystal substrate 5 is 3.8, since a wavelength of a frequency signal in a dielectric is equal to a value obtained by dividing the wavelength in vacuum by a value of one-half power of the relative dielectric constant of the dielectric. Therefore, by forming an inductance element 11 and capacitors 12, 15 (equivalent to a later-described circuit part 10) in a region of about one tenth of the apparent wavelength of the frequency signal, that is, about 1.5 mm to 2.0 mm, on the substrate, it becomes possible to treat the circuit part 10 on substrate as a lumped constant circuit. In a case of the region of about 1.5 mm to 2.0 mm, it is possible to form the inductance element 11 and the capacitors 12, 15 by using photolithography as will be described later.

Hereinafter, concrete configurations of the inductance element 11 and the capacitors 12, 15 will be described. On the quartz crystal substrate 5, as shown in FIG. 6, there is formed a coplanar line which is constituted by a ground electrode 51 and conductive lines 6 for electrically connecting the above-described electronic components respectively on the quartz crystal substrate 5 and which is formed of a metal film in which Cr (chromium) and Cu (copper), for example, are stacked in this order from a bottom side, where these ground electrode 51 and conductive lines 6 are disposed to be separated from each other.

Here, FIG. 6 is a diagram enlargedly showing a part of a region on the quartz crystal substrate 5 which is cut out, and hatching is provided to a region equivalent to the ground electrode 51 and the circuit part 10 on substrate which will be described later. Further, in FIG. 6, reference symbols B, E and C are given to connection terminals 8 of the conductive lines 6 connected to the base, emitter and collector of the transistor 21 inside the IC circuit part 3, respectively.

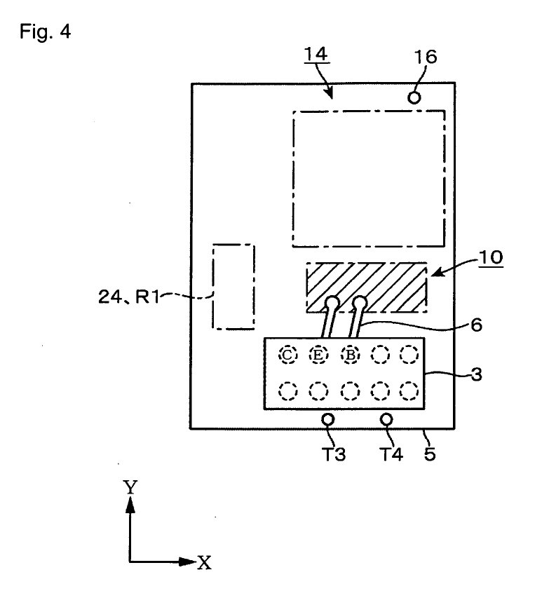

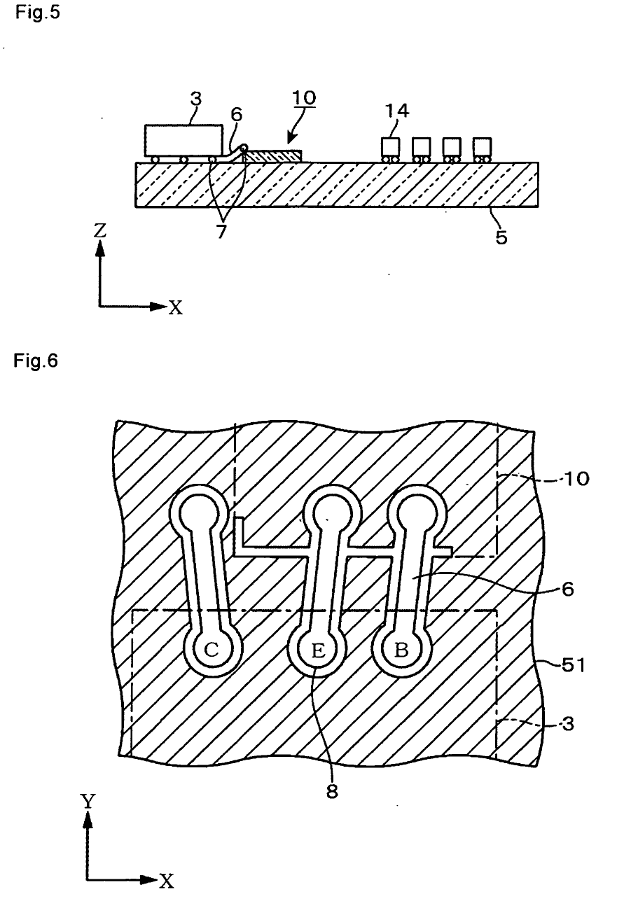

Among the above-described electronic components, various electronic components except the circuit part 10 on substrate are, as shown in FIG. 5, fixed on the quartz crystal substrate 5 by soldering or the like for example, via a pad part 7, and the respective connection terminals 8 and the conductive lines 6 are electrically connected. Then, though illustration is omitted in FIG. 3 and FIG. 4, those electronic components are connected by the above-described conductive lines 6 routed around the quartz crystal substrate 5, so that the electric circuit of the VCO is configured as aforementioned FIG. 1. It should be noted that in FIG. 3 and FIG. 5, illustration of the conductive line 6 is omitted, and in FIG. 4 and FIG. 6 only a part of the conductive lines 6 is illustrated.

Here, the emitter resistance R1 which constitutes the bias circuit and which is provided outside the IC circuit part 3 and the inductor 24 in its previous stage are, as shown in FIG. 3 and FIG. 4 for example, disposed in a position which does not directly face the connection terminal 8 (T2) of the emitter, across the circuit part 10 on substrate on which the capacitor 23 is provided, whereby a stray capacitance is hard to be formed between the pad parts 7 of the emitter resistance R1 and the IC circuit part 3.

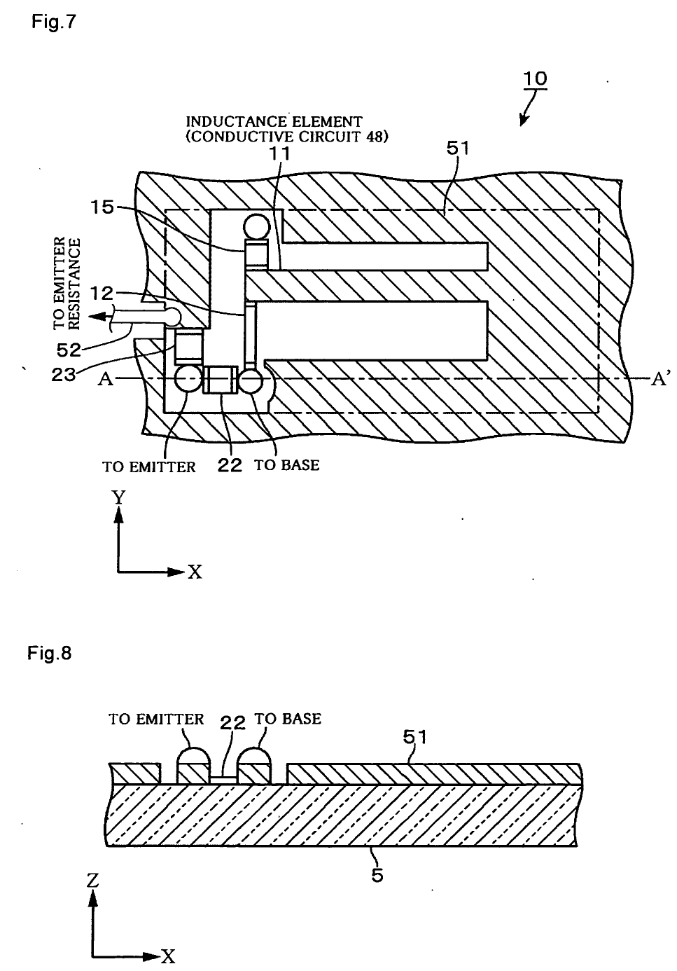

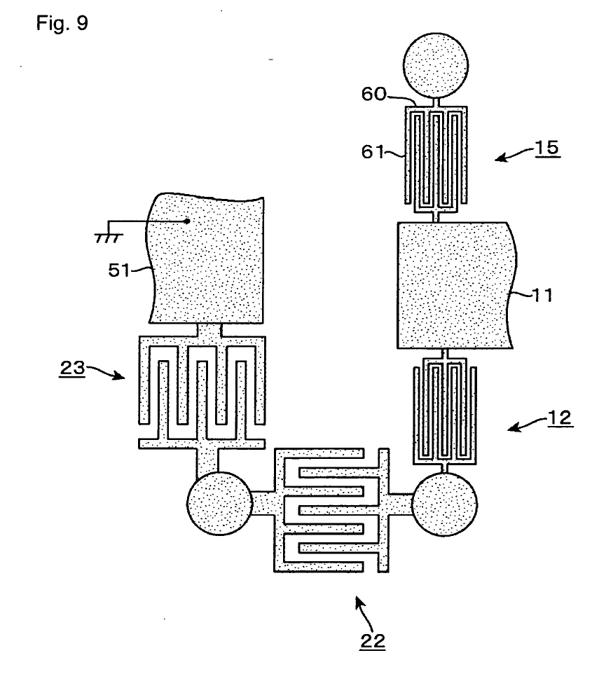

Further, the inductance element 11 and the capacitors 12, 15 of the resonance part 1 and the capacitors 22, 23 of the feedback part 2 are, as shown in FIG. 3, FIG. 4 and FIG. 7, FIG. 8, directly formed in predetermined regions in an upper surface side of the quartz crystal substrate 5 for example, by photolithography or the like. If a circuit portion constituted by the inductance element 11 and the capacitors 12, 15 of the resonance part 1 as well as the capacitors 22, 23 of the feedback part 2, which are formed within the region, is referred to as a circuit part 10 on substrate, the circuit part 10 on substrate is connected to the IC circuit part 3 or the like by the conductive lines 6 formed on the quartz crystal substrate 5 as shown in FIG. 5, and FIG. 6, thereby to constitute the VCO.

Though illustration is simplified in FIG. 7, the capacitors 12, 15, 22, 23 constituting the circuit part 10 on substrate are in practice constituted by comb electrodes for example, as shown in FIG. 9, and are connected to the connection terminals 8 and the inductance element 11, respectively. On the other hand, the inductance element 11 of the resonance part 1 is configured as a strip line composed of a conductive line 48, as shown in FIG. 7, for example.

A region in one end side of this inductance element 11 is sandwiched by the aforementioned two capacitors 12, 15, while the other end side is connected to the ground electrode 51 formed on a quartz crystal substrate 5 surface. Further, as for the capacitor 23, a common electrode in one end side connected to the comb electrode is connected to the connection terminal 8 in an emitter side, while a common electrode in the other end side is connected to the ground electrode 51. Then, from the ground electrode 51 connected to the capacitor 23, a conductive line 52 extends toward an inductor 24 side disposed in a side of the circuit 10 on substrate as shown in FIG. 7, and the connection line is connected to the emitter resistance R1 via the inductor 24.

Here, FIG. 8 shows a vertical sectional side view in which the quartz crystal substrate 5 is cut along A-A′ line shown in FIG. 7, and FIG. 9 is a diagram enlargedly showing a part of the circuit part 10 on substrate shown in FIG. 7.

A method for manufacturing the above-described VCO will be described briefly. For example, first, numerous comb electrodes described above are formed on a quartz crystal wafer in a layout shown in aforementioned FIG. 7 as the capacitors 12, 15, 22, 23. Subsequently, the conductive line 48 is disposed on the quartz crystal wafer, so that a pattern of the inductance element 11 is formed, to form the circuit part 10 on substrate and to form the ground electrode 51. Next, the quartz crystal wafer is cut by dicing or the like for example, thereby to individualize (to divide into chips) the quartz crystal substrate 5, and the components such as the IC circuit part 3 and the varicap diode 14 are soldered to the pad portion 7 printed on the wafer-shaped quartz crystal substrate 5, for example. Thereafter, a not-shown cap is attached in a manner to cover the respective components on the quartz crystal substrate 5, whereby the VCO is manufactured.

The VCO according to the present embodiment brings about a following effect. Since the base bleeder resistances R2, R3 are formed inside the IC circuit part 3 common to the transistor 21, it is possible to reduce the stray capacitance which occurs between the pad parts in the oscillation frequency region of high frequency when the base bleeder resistances R2, R3 and the IC circuit are formed as different bodies. Further, with regard to the emitter resistance R1 which gives small influence on occurrence of the stray capacitance, making the emitter resistance R1 be the resistance element being the different body from the IC circuit part 3 facilitates adjustment of the operating point of the transistor, compared with a case that the emitter resistance R1 is also formed inside the IC circuit part 3.

Further, by forming the inductance element 11 and the capacitors 12, of the resonance part 1 as well as the capacitors 22, 23 of feedback part 2 on the quartz crystal substrate 5 with the small relative dielectric constant as the circuit part 10 on substrate, the apparent wavelength of the frequency signal oscillated from the circuit part 10 on substrate can be made longer, compared with a case that the circuit part 10 on substrate is formed on conventional LTCC, for example. As a result, there are exhibited characteristics (relative dielectric constant ∈ᵣ, tan δ) better than in a case of a fluorocarbon resin or the LTCC which have been conventionally used as a substrate of an inductance element 11 and a capacitor 12. Moreover, since the quartz crystal substrate 5, on which a minute pattern of a metal film can be formed by a photolithography method, is used, it is possible to obtain a low phase noise characteristic in a wide adjustment band.

Further, by forming the inductance element 11 and the capacitors 12, of the resonance part 1 as well as the capacitors 22, 23 of the feedback part 2 (circuit part 10 on substrate) on the quartz crystal substrate, it becomes possible that the circuit part 10 on substrate is treated as a lumped constant circuit thereby to stably oscillate a frequency signal of a high frequency band such as of several GHz or several tens of GHz, for example.

Here, though quartz crystal has been conventionally used as a device of a piezoelectric element using an elastic wave, in the present invention attention is focused on superior physical properties (tan δ and relative dielectric constant ∈ᵣ) of quartz crystal and a fact that a minute pattern of a metal film can be formed on a surface by a photolithography method, and the inductance element 11 and the capacitors 12, 15 constituting the resonance part 1 and the capacitors 22, 23 of the feedback part 2 are formed on the quartz crystal substrate 5.

Further, though in this example the configuration example is shown in which another circuit part 3, the varicap diode 14 and so on are disposed on the quartz crystal substrate 5 on which the circuit part 10 on substrate is formed, those other circuits and so on are not necessarily required to be disposed on the quartz crystal substrate 5. For example, a VCO can be configured as a result that respective elements (inductance element 11 and capacitors 12, 15 of the resonance part 1, and capacitors 22, 23 of the feedback part 2) equivalent to the circuit part 10 on substrate shown in FIG. 7 to FIG. 9 are formed on a common quartz crystal substrate while a quartz crystal chip which can be treated as a lumped constant circuit is created separately, the quartz crystal chip being disposed on a substrate made of a fluorocarbon resin or of LTCC, for example, on which another circuit part 3, the varicap diode 14 and so on are disposed.

Further, the present invention is not limited to a case of application to the VCO in which the resonance part 1 and the feedback part 2 are formed on the quartz crystal substrate 5 or the quartz crystal chip. For example, also in a case that a VCO is configured by providing a resonance part 1, a feedback part 2, and an IC circuit part having a transistor 21 on a ceramic substrate such as LTCC, by forming base bleeder resistances R2, R3 in the IC circuit part 3, deterioration of a frequency characteristic due to occurrence of a stray capacitance can be suppressed. Further, by providing an emitter resistance R1 outside the IC circuit part 3, a degree of freedom of operating point adjustment of the transistor 21 becomes high.

Further, each element disposed on the quartz crystal substrate 5, the quartz chip, or the ceramic substrate is not limited to a specific mode. It can be configured that, with regard to the capacitors 12, 15, 22, 23, instead of the comb electrodes, two electrode lines are faced to each other for example, thereby to store an electric charge between those lines, or a multi-layer ceramic capacitor can be used. With regard to the inductance element 11 also, a conductive line bent zig-zag can be used instead of the straight conductive line 48, or a winding such as a toroidal coil can be used.

For the transistor illustrated in FIG. 1, another transistor such as a FET (field effect transistor) and a logic element made by IC-configuring such a transistor can be used. It should be noted that if the FET is used, emitter/collector/base of the transistor each correspond to source/drain/gate in circuit explanation.

(Simulation)

A simulation model of a VCO is created and a negative resistance indicating stability of an oscillation operation of a transistor 21 is examined.

### A. Simulation Condition

### Example

There is created a model of a VCO with a design frequency of 10 GHz in which base bleeder resistances R2, R3 among a bias circuit are housed inside an IC circuit part 3 and an emitter resistance R1 is formed outside the IC circuit part 3 as shown in FIG. 1, and a frequency characteristic of a negative resistance of a transistor 21 is examined.

### Comparative Example 1

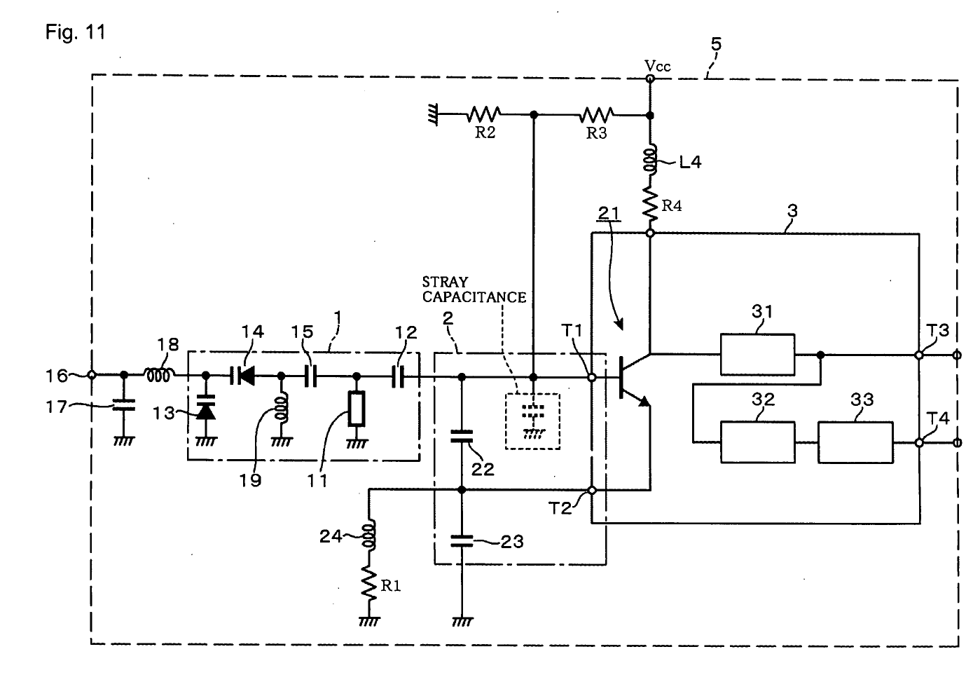

There is created a model of a VCO with a design frequency of 10 GHz in which an emitter resistance R1 and base bleeder resistances R2, R3 which constitute a bias circuit are all formed outside an IC circuit 3 as shown in FIG. 11, and a frequency characteristic of a negative resistance of a transistor 21 is examined. A relative dielectric constant of a base substrate in simulating a stray capacitance between pads is ∈ᵣ=5.

### Comparative Example 2

In a simulation model similar to that of (Comparative Example 1), a frequency characteristic of a negative resistance is examined with a relative dielectric constant of a base substrate being ∈ᵣ=7.

### Reference Example

In a simulation model similar to that of (Comparative Example 1), a frequency characteristic of a negative resistance is examined with influence of a stray capacitance among between pads being excluded.

### B. Simulation Result

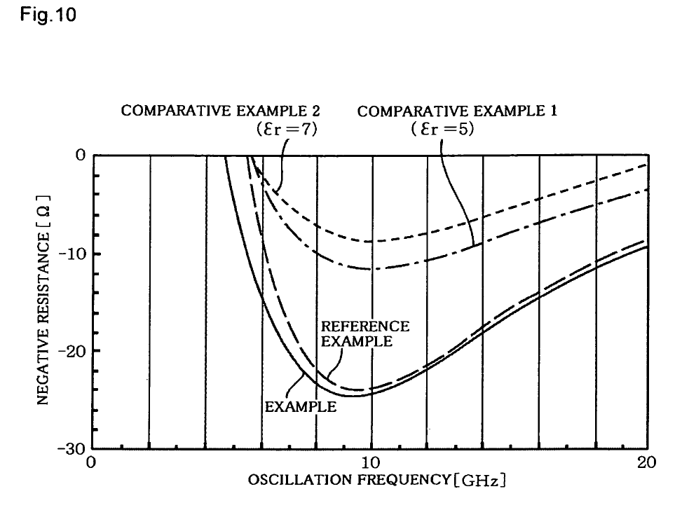

Results of simulations according to the example, the comparative examples, and the reference example are shown in FIG. 10. In FIG. 10, a horizontal axis indicates an oscillation frequency [GHz], while a vertical axis indicates a negative resistance [Ω]. In FIG. 10, the simulation result of (Example) is indicated by a solid line, the simulation result of (Comparative Example 1) is indicated by a dashed line, and the simulation result of (Comparative Example 2) is indicated by a short broken line. Further, the simulation result of (Reference Example) is indicated by a long broken line.

According to the simulation result shown in FIG. 10, the frequency characteristic of the negative resistance of the transistor 21 according to (Example) exhibits a curve projecting downward, which represents that the negative resistance becomes minimum at the oscillation frequency around 10 GHz. A minimum value of the negative resistance is about −24Ω.

In contrast, the frequency characteristics of the negative resistances in (Comparative Examples 1, 2) are common to a case of (Example) in that curves projecting downward are exhibited which represent that the values of the negative resistances become minimum at oscillation frequencies around 10 GHz. However, both of the negative resistances of (Comparative Examples 1, 2) have higher values than the negative resistance of (Example) in all the range (6 GHz to 20 GHz) of (Comparative Examples 1, 2) shown in FIG. 10, and it is recognized that oscillation operations are unstable.

Here, in (Comparative Examples 1, 2), it is recognized that the frequency characteristic of the negative resistance according to (Reference Example) in which the influence of the stray capacitance between pads is excluded exhibits a characteristic close to that of (Example). Therefore, it can be confirmed that an existence of a stray capacitance raises a negative resistance, causing deterioration of an oscillation characteristic of a VCO. Further, the above matches a fact that in comparison with (Comparative Example 1) and (Comparison Example 2) the negative resistance tends to be higher in (Comparative Example 2) in which a value of the relative dielectric constant ∈ᵣ is high and a large stray capacitance occurs.

According to the above-described simulation results, it can be said that by providing base bleeder resistances R2, R3 inside an IC circuit part 3 thereby to suppress occurrence of a stray resistance between pads a VCO capable of oscillating a frequency signal having a good frequency characteristic can be obtained.

Even in a case that an emitter resistance R1 is provided outside an IC circuit part 3, since a stray capacitance occurring in a pad of the resistance R1 can be balanced out by a capacitance value of a capacitor 23 as stated above, a frequency characteristic almost similar to the frequency characteristic of the negative resistance according to (Example) can be obtained.

Further, in the examples of VCO's described in (Example), (Comparative Examples 1, 2), as a result that the VCO's with design frequency of 10 GHz are used, a difference of the negative resistances between (Example) and (Comparative Examples 1, 2) is the largest at the frequency around 10 GHz. The present inventor grasps that, though a difference between the negative resistances changes also by a design condition of the VCO, influence of a stray capacitance occurring between pads cannot be ignored when an oscillation frequency becomes equal to or more than 5 GHz, for example.

What is claimed is:

1. A voltage controlled oscillator, comprising:
a resonance part which includes a variable capacitance element where an electrostatic capacitance changes in correspondence with a control voltage for frequency control inputted from the outside, and an inductance element, and in which a resonance frequency is adjusted in correspondence with the electrostatic capacitance;
a transistor of grounded emitter type to amplify a frequency signal inputted from said resonance part to a base terminal;
a feedback part which includes a capacitance element for feedback, feedbacks a frequency signal outputted from an emitter terminal of said transistor to said transistor via the base terminal, and constitutes an oscillation loop together with said transistor and said resonance part;
a base bleeder resistance to adjust a bias voltage applied to the base terminal of said transistor; and
an emitter resistance which is provided between the emitter terminal of said transistor and a ground in order to adjust an operating point of said transistor,
wherein while said transistor and said base bleeder resistance are formed in a common integrated circuit, said emitter resistance is constituted by a resistance element being a different body from the integrated circuit, and the voltage controlled oscillator is configured by providing the integrated circuit, the resistance element, said resonance part, and said feedback part on a common substrate.

2. The voltage controlled oscillator according to claim 1,
wherein the substrate is a quartz crystal substrate.

3. The voltage controlled oscillator according to claim 1,
wherein the resonance frequency is equal to or more than 5 GHz.
